(19) United States
(12) Patent Application Publication
(10) Pub. No.: US 2017/0361770 A1
(43) Pub. Date: Dec. 21, 2017

(54) VEHICLE HORN DEVICE AND METHOD

(71) Applicant: Robert Larsen, Lynnwood, WA (US)

(72) Inventor: Robert Larsen, Lynnwood, WA (US)

(21) Appl. No.: 15/291,654

(22) Filed: Oct. 12, 2016

Related U.S. Application Data
(60) Provisional application No. 62/351,793, filed on Jun. 17, 2016.

(51) Int. Cl. B60Q 5/00; G06F 3/16; H03G 3/04; H03G 5/04

(52) U.S. Cl. CPC B60Q 5/003; H03G 5/04; G06F 3/165; H03G 3/04

(57) ABSTRACT

The electronic communication system for a vehicle includes a processor, a memory, an audio output device, a power supply, and a controller. The electronic communication system for a vehicle is useful for storing and accessing sound files, which may include the brand name of an automobile, and emitting audible communications to the environment external to a vehicle.

### CROSS-REFERENCE TO RELATED APPLICATION

The present application is related to and claims priority to U.S. Provisional Patent Application No. 62/351,793 filed 17 Jun. 2016, which is incorporated by reference herein in its entirety.

### BACKGROUND OF THE INVENTION

The following includes information that may be useful in understanding the present disclosure. It is not an admission that any of the information provided herein is prior art nor material to the presently described or claimed inventions, nor that any publication or document that is specifically or implicitly referenced is prior art.

### 1. Field of the Invention

The present invention relates generally to the field of electronic communications and more specifically relates to audible indications of vehicles.

### 2. Description of Related Art

Automobile and vehicle manufacturers provide vehicle horn tones to comply with standards. These standards dictate that the horn tone be set in relation to the vehicle size. The larger the vehicle, the lower the tone, and vice versa. These horn tones, and the volume of the horn tones, are set when the automobile or vehicle is manufactured and are not customizable by the owner. A suitable solution is desired.

U.S. Pub. No. 2012/0299748 to Reid relates to a promotional vehicle audio system. The described promotional vehicle audio system includes a voice synthesizer to play a horn tone “Jeep, Jeep” imitating the “Beep, Beep” voice, cadence, and rhythm of the Road Runner®. This is specific to the Jeep® brand and enables the user to either use the existing factory horn, or a separate loudspeaker to play the new horn tone as desired. The main elements of the system are a voice synthesizer, a loudspeaker, and an engagement device mounted on or near the steering wheel, which will operate the voice synthesizer and can be used to project the promotional message, “Jeep, Jeep” via the vehicle horn.

### BRIEF SUMMARY OF THE INVENTION

In view of the foregoing disadvantages inherent in the known electronic communications art, the present disclosure provides a novel vehicle horn device. The general purpose of the present disclosure, which will be described subsequently in greater detail, is to provide a vehicle horn device.

An electronic communication system for a land vehicle is disclosed herein. The electronic communication system for a land vehicle includes a processor, a memory configured to store at least one sound file executable via the processor, an audio output device configured to emit audible communications from the at least one sound file to an environment external to the land vehicle, a power supply configured to receive electrical energy from an electrical system of the land vehicle, and to provide power to the audio output device, and a controller including an audio selector configured to select from a plurality of audio output files stored in the memory, and an activation switch configured to power and activate the audio output device to emit said audible communications from the at least one sound file to an environment external to the land vehicle.

According to another embodiment, a method of installing the above vehicle horn device is also disclosed herein. The method of installing the vehicle horn device includes the steps of mounting the horn to the interior surface of the vehicle via the mounting bracket, coupling at least one standardized data connection with the input interface, coupling the audio output device with an output interface of the housing, connecting the power supply to receive electrical power from the vehicle, co-locating the activation means proximate to a user-seat in said vehicle interior, and sounding the horn via said activation means.

For purposes of summarizing the invention, certain aspects, advantages, and novel features of the invention have been described herein. It is to be understood that not necessarily all such advantages may be achieved in accordance with any one particular embodiment of the invention. Thus, the invention may be embodied or carried out in a manner that achieves or optimizes one advantage or group of advantages as taught herein without necessarily achieving other advantages as may be taught or suggested herein. The features of the invention which are believed to be novel are particularly pointed out and distinctly claimed in the concluding portion of the specification. These and other features, aspects, and advantages of the present invention will become better understood with reference to the following drawings and detailed description.

### BRIEF DESCRIPTION OF THE DRAWINGS

The figures which accompany the written portion of this specification illustrate embodiments and methods of use for the present disclosure, a vehicle horn device, constructed and operative according to the teachings of the present disclosure.

FIG. 1 is a side view of a land vehicle including an electronic communication system for a land vehicle during an ‘in-use’ condition, according to an embodiment of the present disclosure.

FIG. 2 is a schematic diagram of the electronic communication system for a land vehicle in an original equipment configuration, according to an embodiment of the present disclosure.

FIG. 3 is schematic diagram of the electronic communication system for a land vehicle in an aftermarket configuration, according to an embodiment of the present disclosure.

FIG. 4 is a schematic diagram of an electronic communication system for a land vehicle, according to yet another embodiment of the present disclosure.

FIG. 5 is a flow diagram illustrating a method of use for an electronic communication system for a land vehicle, according to an embodiment of the present disclosure.

The various embodiments of the present invention will hereinafter be described in conjunction with the appended drawings, wherein like designations denote like elements.

### DETAILED DESCRIPTION

As discussed above, embodiments of the present disclosure relate to electronic communications and more particularly to a vehicle horn device, as used to improve electronic communication systems.

Generally, disclosed herein is a vehicle horn, which may comprise a custom vehicle horn for Jeep brand automobiles. When activated, the vehicle horn may comprise the sound “Jeeeeeep”. The vehicle horn may be activated via the factory-installed horn activator button. Other automobile brand sounds can also be produced using teachings described herein.

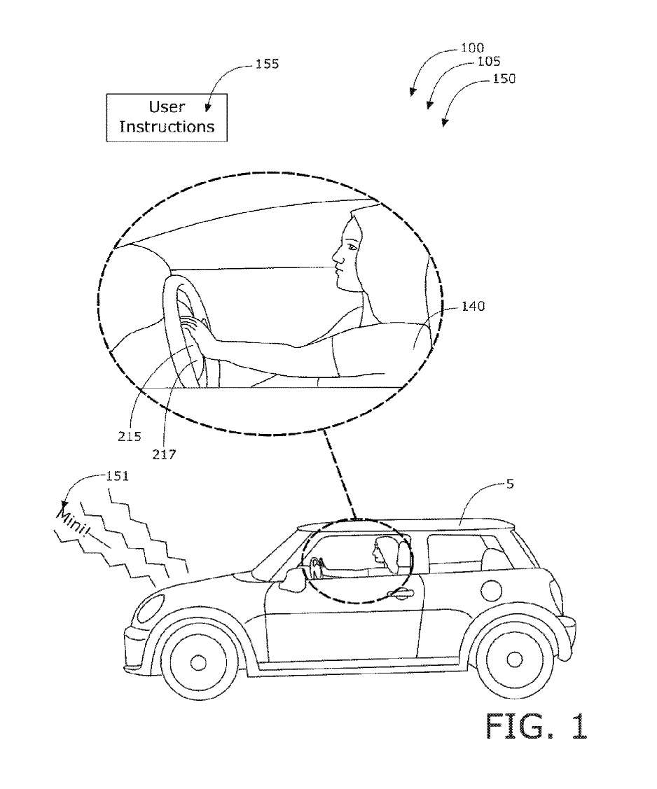

Referring now more specifically to the drawings by numerals of reference, there is shown in FIGS. 1-4, various views of an electronic communication system 100.

FIG. 1 shows an electronic communication system during an ‘in-use’ condition 150, according to an embodiment of the present disclosure. Here, the electronic communication system 100 may be beneficial for use by a user 140 to provide audible indications. As illustrated and discussed further below, the electronic communication system 100 may include elements that are able to emit audible communications 151 to an environment which may be external to a land vehicle 5.

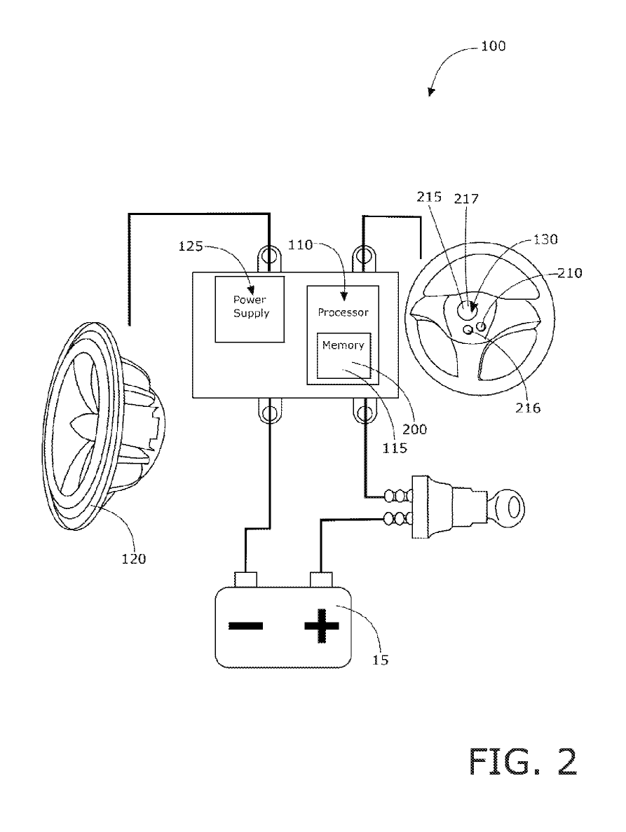

The audible communications 151 may include at least one of spoken words, musical notes, and alternately, horn sounds. The horn sounds may further include auto horn sounds. The user 140 may initiate or sound the audible communications 151 from an activation switch 215 that may be configured to power and activate an audio output device 120 (FIG. 2). According to this embodiment, the activation switch 215 may be the steering-wheel horn pushbutton 217, commonly used in land vehicles 5.

According to one embodiment, the electronic communication system 100 may be arranged as a kit 105. In particular, the electronic communication system 100 may further include a set of instructions 155. The instructions 155 may detail functional relationships in relation to the structure of the electronic communication system 100 (such that the electronic communication system 100 can be used, maintained, or the like, in a preferred manner).

FIG. 2 shows the electronic communication system 100 of FIG. 1, according to an embodiment of the present disclosure. Here, the electronic communication system 100 is integrated with the land vehicle 5 (FIG. 1) as original equipment. The electronic communication system 100 may include a processor 110, a memory 115, an audio output device 120, a power supply 125, and a controller 130. The processor 110 may be configured to execute at least one sound file 200 that is stored on and accessible from the memory. The processor 110 may be further configured to translate the at least one sound file 200 to an audio output device 120 to emit audible communications 151 (FIG. 1) to an environment external to the land vehicle 5.

The at least one sound file 200 may include at least one of spoken words, musical notes, and horn sounds. The spoken words may include the name of at least one automobile manufacturer, and alternately the name of at least one type of automobile to enable a user-owner to have a non-traditional horn sound. This may allow the user-owner to express pride in driving the product of the at least one automobile manufacturer, and alternately pride in driving the specific type of automobile when “honking” the horn.

Further, the at least one sound file 200 may be configured to repeat the name of the at least one automobile manufacturer, and alternately the name of the at least one type of automobile, for a user-selected number of iterations. As mentioned above, at least one sound file 200 may include horn sounds, with the horn sounds further including auto horn sounds as additional choices for the user-owner. In addition, the at least one sound file 200 may be configured to be able to change, and alternatively add, additional audible communications 151 such as a theme song from a favorite television show, a favorite sports team fight song, and the like.

The power supply 125 for the electronic communication system 100 may be powered off-board, thus being configured to receive electrical energy from an electrical system 15 of the land vehicle 5, and provide electrical power to the audio output device 120.

The controller 130 may be configured as a user-interface, and may include an activation switch 215. The controller 130 may further include an audio selector 210 and a volume adjuster 216. The audio selector 210 may be configured to select from a plurality of audio output files (sound file 200) stored in the memory 115 of the processor 110. In addition, the activation switch 215 may be configured to power and activate the audio output device 120 to emit the audible communications 151 (FIG. 1) from at least one sound file 200 to an environment external to the land vehicle 5 (FIG. 1). According to one embodiment, the activation switch 215 may be a steering-wheel horn pushbutton of the land vehicle 5, and the audio selector 210 and the volume adjuster 216 may be also integrated into the steering-wheel horn pushbutton. Further, the volume adjuster 216 may be configured so that the user 140 (FIG. 1) may vary the volume level of the output from the audio output device 120.

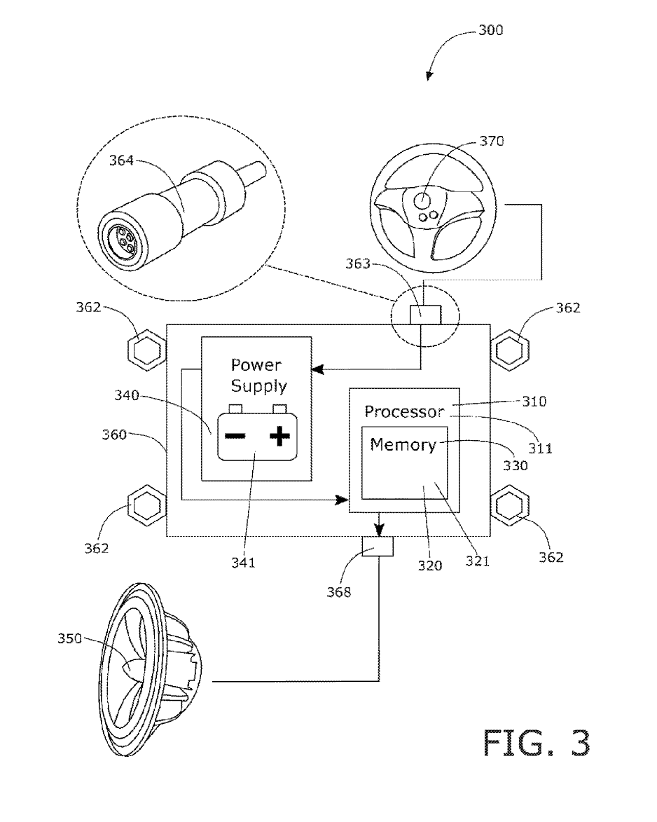

FIG. 3 is a schematic diagram of an electronic communication system for a land vehicle according to an alternative embodiment. Here, the electronic communication system 100 is added to the land vehicle 5 (FIG. 1) an aftermarket configuration. In this embodiment, the electronic communication system for a land vehicle 300 may supplement the existing audible horn system of the vehicle 5. The horn for a vehicle 300 may include a processor 310, a memory 330, at least one power supply 340, an audio output device 350, a housing 360, and activation means 370. The activation means 370 may be configured to be controlled by a user 140 (FIG. 1) from the vehicle interior, and further configured to initiate the audible non-conventional horn sound to an environment external to the vehicle 5.

The processor 310 may include a signal processor 311, a memory 330, and at least one power supply 340. The signal processor 311 may be configured to index and play digital sound files 320 from the memory 330, with the memory 330 configured to store at least one digital sound file 321 that may be executable via the processor 310. In further referring to the digital sound files 320, the digital sound files 320 may include at least one of voice, music, and traditional horn sounds, which may include traditional auto horn sounds. The processor 310 may be configured to direct digital sound files 320 to an audio output device 350 that may emit a non-conventional horn sound 327 to an environment external to the vehicle 5.

The electronic communication system for a land vehicle 300 may be configured to include at least one power supply 340 that may further be configured to provide operating power to the vehicle horn 35. In one embodiment of the present disclosure, the at least one power supply 340 may be a rechargeable, self-contained battery 341. Alternately, the at least one power supply 340 may be configured to receive electrical power 20 from the vehicle 5.

The signal processor 311, the memory 330, and the at least one power supply 340 may be contained in a housing 360 configured to fixedly-retain the processor 310, the memory 330, and the power supply 340. The exterior of the housing 360 may be configured to mount to an interior surface of the vehicle 5 via at least one mounting bracket 362. Further, the housing 360 may be of ruggedized construction to withstand varying ambient conditions and protect the processor 310, the memory 330, and the power supply 340 within the housing 360. The housing 360 may include an input interface 363 configured to removably couple with at least one type of standardized data connection 364. At least one standardized data connection 364 may include at least one of a USB connector, a threaded connector with a back shell, and the like. Alternately a wireless communication connection may be used. The housing 360 may also include an output interface 368, which may be configured to removably couple with the audio output device 350. Further, the audio output device 350 may be selected from a group which may include an analog speaker, a digital audio player, and a vehicle horn.

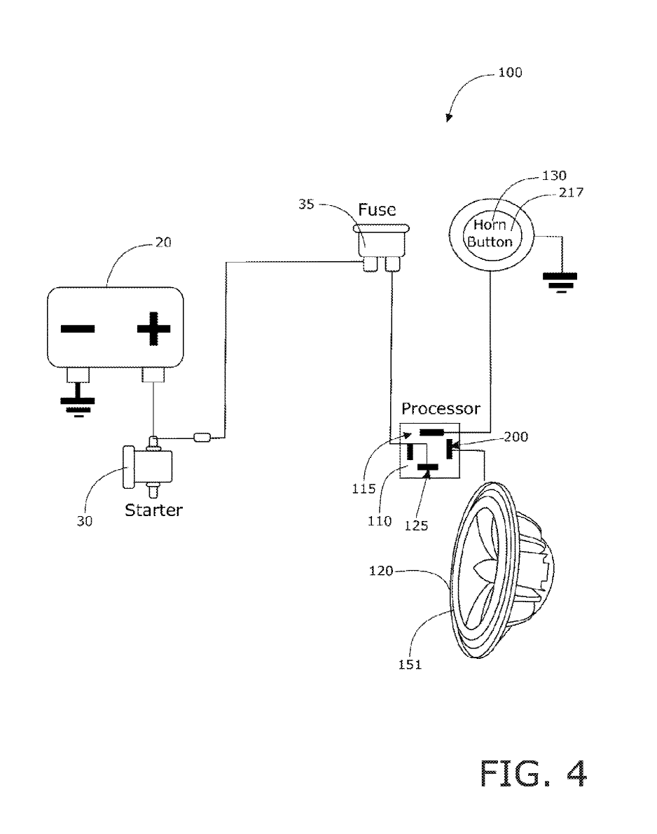

FIG. 4 is a schematic diagram of the electronic communication system 100 of FIG. 1, according to an embodiment of the present disclosure. The electronic communication system 100 for a vehicle 5 (FIG. 1) may include the processor 110, a memory 115, an audio output device 120, a power supply 125, and a controller 130. When electrical power 20 is available after engaging the starter 30 of the vehicle 5, the electrical current flows through the fuse 35 and is made available to the power supply 125 located within the processor 110. Upon activation of the controller 130, which may be the steering-wheel horn pushbutton 217, the power supply 125 powers the processor 110 to access the memory 115 to retrieve and process the at least one sound file 200 to emit audible communications 151 to an audio output device 120.

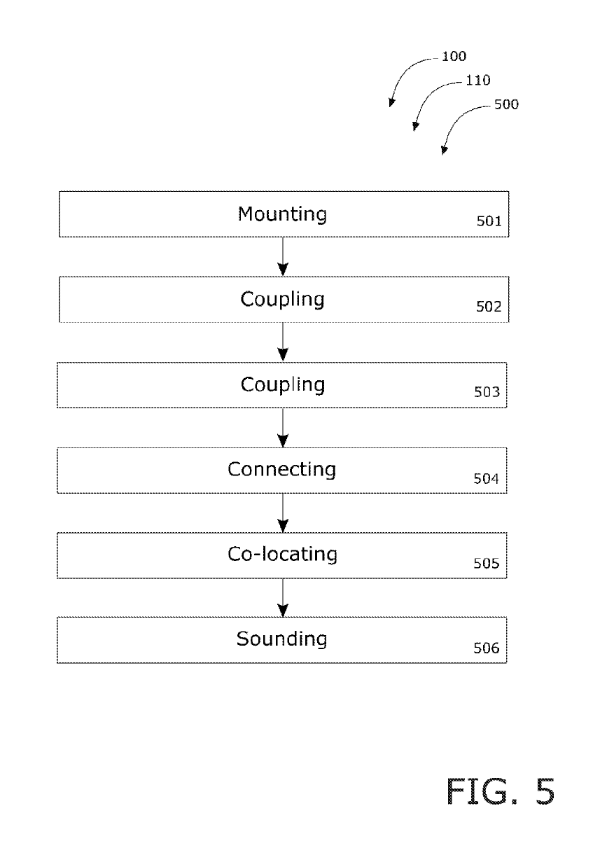

FIG. 5 is a flow diagram illustrating a method for electronic communication system, according to an embodiment of the present disclosure. In particular, the method for electronic communication system for a vehicle 500 may include one or more components or features of the electronic communication system for a vehicle 100 as described above. As illustrated, the method for use of an electronic communication system 500 may include the steps of: step one 501, mounting the horn to the interior surface of the vehicle via the mounting bracket; step two 502, coupling at least one standardized data connection with the input interface; step three 503, coupling the audio output device with an output interface of the housing; step four 504, connecting the power supply to receive electrical power from the vehicle; step five 505, co-locating the activation means proximate to a user-seat in said vehicle interior; and step six 506, sounding the horn via the activation means.

It should be noted that the steps described in the method of use can be carried out in many different orders according to user preference. The use of “step of” should not be interpreted as “step for”, in the claims herein and is not intended to invoke the provisions of 35 U.S.C. §112(f). It should also be noted that, under appropriate circumstances, considering such issues as design preference, user preferences, marketing preferences, cost, structural requirements, available materials, technological advances, etc., other methods for electronic communication system for a vehicle (e.g., different step orders within above-mentioned list, elimination or addition of certain steps, including or excluding certain maintenance steps, etc.), are taught herein.

The embodiments of the invention described herein are exemplary and numerous modifications, variations and rearrangements can be readily envisioned to achieve substantially equivalent results, all of which are intended to be embraced within the spirit and scope of the invention. Further, the purpose of the foregoing abstract is to enable the U.S. Patent and Trademark Office and the public generally, and especially the scientist, engineers and practitioners in the art who are not familiar with patent or legal terms or phraseology, to determine quickly from a cursory inspection the nature and essence of the technical disclosure of the application.

What is claimed is new and desired to be protected by Letters Patent is set forth in the appended claims:

1. An electronic communication system for a land vehicle, the electronic communication system comprising:
a processor;
a memory configured to store at least one sound file executable via the processor;
an audio output device configured to emit audible communications from the at least one sound file to an environment external to the land vehicle;
a power supply configured to receive electrical energy from an electrical system of the land vehicle, and to provide power to the audio output device; and
a controller including an audio selector and an activation switch, said audio selector configured to select from a plurality of audio output files stored in the memory, said activation switch configured to power and activate the audio output device to emit said audible communications from the at least one sound file to an environment external to the land vehicle.

2. The electronic communication system of claim 1, wherein the activation switch is a steering-wheel horn pushbutton.

3. The electronic communication system of claim 2, wherein the audio selector is integrated into the steering-wheel horn pushbutton.

4. The electronic communication system of claim 1, wherein the at least one sound file includes at least one of spoken words, musical notes, and horn sounds including auto horn sounds.

5. The electronic communication system of claim 4, wherein the spoken words include a name of at least one automobile manufacturer.

6. The electronic communication system of claim 4, wherein the spoken words include a name of at least one type of automobile.

7. The electronic communication system of claim 4, wherein the spoken words include a name of at least one automobile manufacturer, and alternately a name of at least one type of automobile; and
wherein the at least one sound file is configured to repeat the name of the at least one automobile manufacturer, and alternately the at least one type of automobile, for a user-selected number of iterations.

8. The electronic communication system of claim 4, wherein the at least one sound file is configured to be able to change, and alternatively add, additional audible communications.

9. The electronic communication system of claim 1, wherein the controller includes a volume, and alternately a tone, adjuster configured to vary a volume level of output of the audio output device.

10. An electronic communication system for a vehicle, the electronic communication system comprising:
a processor;
a memory configured to store at least one digital sound file executable via the processor;
a power supply configured to provide operating power to the electronic communication system;
an audio output device configured to emit a non-conventional horn sound to an environment external to the vehicle;
a housing having an inner volume configured to fixedly-mount the processor, the memory, and the power supply within the inner volume of the housing, the housing configured to mount to an interior surface of the vehicle via at least one mounting bracket; and
activation means configured to be controlled from inside the vehicle, and further configured to initiate the audible non-conventional horn sound to an environment external to the vehicle.

11. The electronic communication system of claim 10, wherein the housing is of ruggedized construction to withstand varying ambient conditions and protect the processor, the memory, and the power supply within the inner volume of the housing.

12. The electronic communication system of claim 10, wherein the housing includes an input interface configured to removably couple with at least one standardized data connection.

13. The electronic communication system of claim 12, wherein the at least one standardized data connection includes at least one of a USB connector, a threaded connector with a back shell, and a wireless communication connection.

14. The electronic communication system of claim 10, wherein the housing includes an output interface configured to removably couple with the audio output device.

15. The electronic communication system of claim 14, wherein the audio output device is selected from a group including an analog speaker, a digital audio player, and a vehicle horn.

16. The electronic communication system of claim 10, wherein the processor includes a signal processor configured to index and play digital sound files including at least one of voice, music, and traditional horn sounds including traditional auto horn sounds.

17. The electronic communication system of claim 10, wherein the at least one power supply is configured to receive electrical power from the vehicle.

18. The electronic communication system of claim 10, wherein the at least one power supply is a rechargeable, self-contained battery configured to reside inside the housing.

19. The electronic communication system of claim 10, further comprising set of instructions; and
wherein the vehicle horn device is arranged as a kit.

20. A method of installing the electronic communication system of claim 12, the method comprising the steps of:
mounting the electronic communication system to the interior surface of the vehicle via the mounting bracket;
coupling the at least one standardized data connection with the input interface;
coupling the audio output device with an output interface of the housing;
connecting the power supply to an electrical power source of the vehicle;
co-locating the activation means proximate a user-seat inside said vehicle; and
sounding the electronic communication system via said activation means.
